(19) United States
(12) Patent Application Publication
(10) Pub. No.: US 2021/0271273 A1
(43) Pub. Date: Sep. 2, 2021

(54) Thermostat

(71) Applicant: Carrier Corporation, Palm Beach Gardens, FL (US)

(72) Inventors: Kevin E. McMurray, Fort Wayne, IN (US); Keith David Heigl, Winamac, IN (US)

(73) Assignee: Carrier Corporation, Palm Beach Gardens, FL (US)

(21) Appl. No.: 17/254,576

(22) PCT Filed: Sep. 27, 2019
(86) PCT No.: PCT/US2019/053420

§ 371 Date: Dec. 21, 2020

Related U.S. Application Data
(60) Provisional application No. 62/758,551, filed on Nov. 10, 2018.

(51) Int. Cl. G05D 23/19; H05K 5/00; F24F 11/89; F24F 11/58

(52) U.S. Cl. CPC G05D 23/1902; F24F 11/58; F24F 11/89; H05K 5/0017

(57) ABSTRACT

A wall mountable user interface unit (20) has first (22) and second (24) sections. The first section (22) has: a body (32) mountable to a wall and having first features (50A, 50B); power relays (104); and a first interface (110) for two-way communication with the second section including a first electrical connector (44). The second section (24) is mountable to and demountable from the first section and has: a body (34) having second features (70A, 70B) for holding the second section to the first section in a mounted condition; a second interface (224) for two-way communication with the first section and including a second electrical connector (46) carried by the second section body and mated to the first electrical connector in the mounted condition; a processor (200); and a display (26).

### CROSS-REFERENCE TO RELATED APPLICATION

Benefit is claimed of U.S. Patent Application No. 62/758,551, filed Nov. 10, 2018, and entitled “Thermostat”, the disclosure of which is incorporated by reference herein in its entirety as if set forth at length.

### BACKGROUND

The disclosure relates to heating ventilation and air conditioning (HVAC) control. More particularly, the disclosure relates to control unit/thermostat construction.

For many decades, a common configuration of residential or commercial HVAC thermostat involves a mounting plate (baseplate) mounted to a surface of an interior building wall and through which control wires for the HVAC system pass. The wires connect to the main thermostat unit or section which, in turn, is mountable to and demountable from the baseplate. This basic configuration has survived from analog thermostats through digital thermostats. An exemplary 2-wire control protocol is disclosed in U.S. Pat. No. 6,956,463, Crenella et al., Oct. 18, 2005, “Method and apparatus for providing both power and communication over two wires between multiple low voltage AC devices”, the disclosure of which is incorporated by reference herein in its entirety as if set forth at length.

In many modern such thermostats, the baseplate and the housing of the main section are molded plastic with snap engagement mating features or the like for mounting.

Alternative proposals have included connecting the wall wiring to an electrical connector on the baseplate to, in turn, mate with a complementary connector of the main unit in the mounted condition. See, U.S. Pat. No. 9,780,511.

### SUMMARY

One aspect of the disclosure involves a wall mountable user interface unit having first and second sections. The first section has: a body mountable to a wall and having first features; power relays; and a first interface for two-way communication with the second section including a first electrical connector. The second section is mountable to and demountable from the first section and has: a body having second features for holding the second section to the first section in a mounted condition; a second interface for two-way communication with the first section and including a second electrical connector carried by the second section body and mated to the first electrical connector in the mounted condition; a processor; and a display.

In one or more embodiments of any of the foregoing embodiments, the first and second interfaces are serial interfaces.

In one or more embodiments of any of the foregoing embodiments, the second section is installable to the first section to mate the second electrical connector to the first electrical connector by a downward translation.

In one or more embodiments of any of the foregoing embodiments, the first section body and the second section body comprise a detent mechanism securing the mounted condition.

In one or more embodiments of any of the foregoing embodiments, the detent mechanism comprises: a pair of upwardly open channels on one of the first section body and the second section body; a detenting projection on a wall of at least one of the upwardly open channels; a pair of holes on the other of the first section body and the second section body complementary to the pair of channels; and at least one detenting hole complementary to the detenting projection.

In one or more embodiments of any of the foregoing embodiments, the wall mountable user interface unit is a thermostat wherein at least one of the first section and second section comprises at least one temperature sensor.

In one or more embodiments of any of the foregoing embodiments, the at least one temperature sensor includes a first temperature sensor being an environmental temperature sensor and a second temperature sensor being an internal PC board temperature sensor.

In one or more embodiments of any of the foregoing embodiments, the first section further comprises: an input/output isolation microcontroller; power switching circuitry; and AC power sensing circuits.

The second section further comprises: volatile memory and non-volatile memory; and a radio for wirelessly communicating with associated HVAC equipment and sensors.

In one or more embodiments of any of the foregoing embodiments, the first section further comprises: a 2-wire interface for equipment control when only two wires for supply power are present in the installation.

In one or more embodiments of any of the foregoing embodiments, the 2-wire interface is configured to communicate and control associated HVAC equipment using voltage 24 VAC power waveform.

In one or more embodiments of any of the foregoing embodiments, the first section is directly fastened to a wall.

Another aspect of the disclosure involves a method for using a wall mountable user interface unit. The wall mountable user interface unit comprising first and second sections. The first section comprises: a body; and a first electrical connector. The second section comprises: a body; a second electrical connector carried by the second section body; a display; and a processor. The method comprises with the first section body mounted to a wall, installing the second section to the first section to mate the second electrical connector to the first electrical connector by a downward translation.

In one or more embodiments of any of the foregoing embodiments, the installing comprises a translation toward the wall prior to the downward translation.

In one or more embodiments of any of the foregoing embodiments, the installing comprises passing features of the first section body through apertures in the second section body.

In one or more embodiments of any of the foregoing embodiments, the installing is a detented installing.

Another aspect of the disclosure involves a wall-mounted user interface unit comprising first and second sections. The first section is mountable to a wall and comprises: a body having first features; and a first electrical connector. The second section is mountable to and demountable from the first section and comprises: a body having second features for holding the second section to the first section in a mounted condition; a second electrical connector carried by the second section body and mated to the first electrical connector in the mounted condition; and a display. With the first section body mounted to a wall, the second section is installable to the first section to mate the second electrical connector to the first electrical connector by a downward translation.

The details of one or more embodiments are set forth in the accompanying drawings and the description below. Other features, objects, and advantages will be apparent from the description and drawings, and from the claims.

### BRIEF DESCRIPTION OF THE DRAWINGS

FIG. 1 is a front view of a thermostat.

FIG. 2 is a top view of the thermostat.

FIG. 3 is a left side view of the thermostat (left from the point of view of a user facing the wall on which the thermostat is mounted).

FIG. 4 is a rear view of the thermostat.

FIG. 5 is a first exploded view of the thermostat.

FIG. 6 is a second exploded view of the thermostat.

FIG. 7 is a right side view of the thermostat in an intermediate condition of mating of two sections.

FIG. 8 is a vertical sectional view of the thermostat taken along line 8-8 of FIG. 1.

FIG. 9 is a view along a plane of FIG. 8 in the intermediate condition.

FIG. 10 is a vertical sectional view of the thermostat taken along line 10-10 of FIG. 1.

FIG. 11 is a view along the plane of FIG. 10 in the intermediate condition.

FIG. 12 is a first side view of a circuit board assembly of a first section of the thermostat.

FIG. 13 is a second side view of the circuit board assembly of the first section of the thermostat.

FIG. 14 is a first side view of a circuit board assembly of a second section of the thermostat.

FIG. 15 is a second side view of the circuit board assembly of the second section of the thermostat.

Like reference numbers and designations in the various drawings indicate like elements.

### DETAILED DESCRIPTION

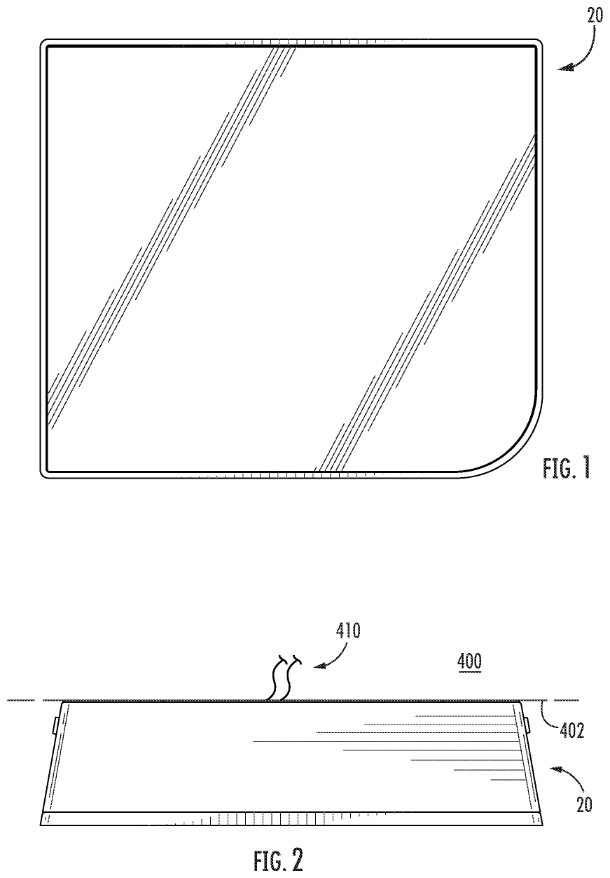

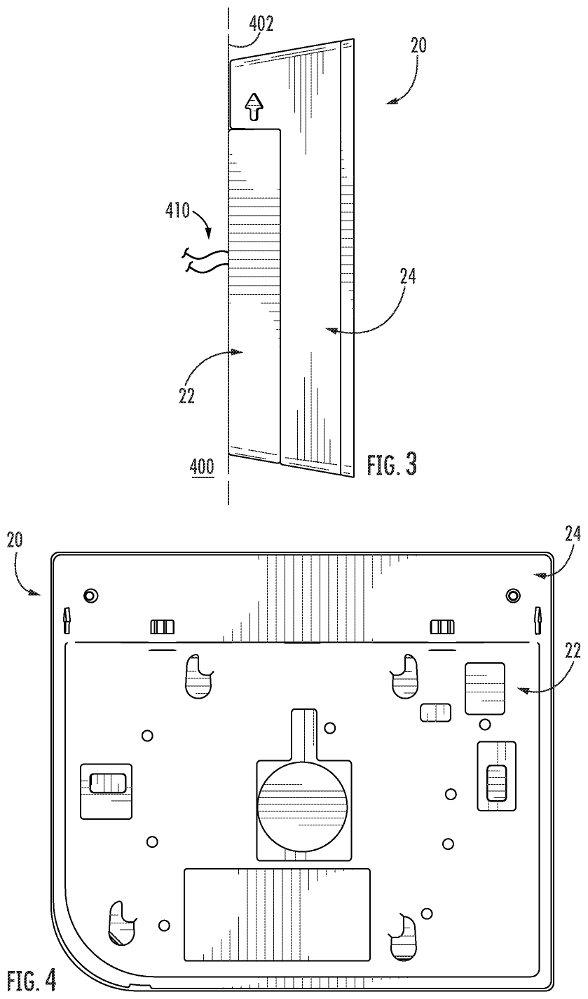

FIG. 1 shows a thermostat 20 having a first section (base unit or wall unit or wall plate) 22 (FIG. 3) for mounting to a surface 402 of an interior wall 400 of a building. Exemplary mounting is via screws (not shown) into the wall with slots in a body of the base unit capturing the heads of the screws. However, other alternative mounting surfaces are possible. FIGS. 2 and 3 further show wiring 410 extending through the wall to/from the base unit. A second section or unit 24 is shown mounted to the base unit 22. The second unit is demountable from the base unit (e.g., non-destructively without tools). The second unit is then similarly re-mountable without tools.

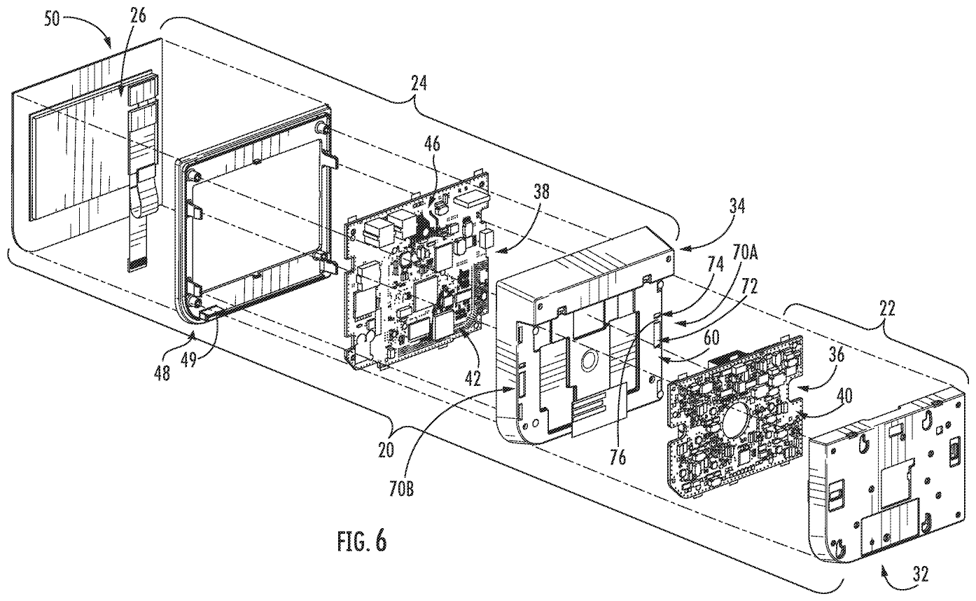

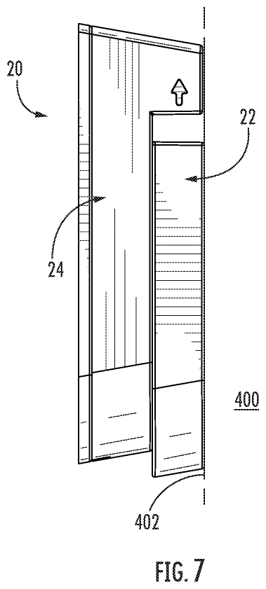

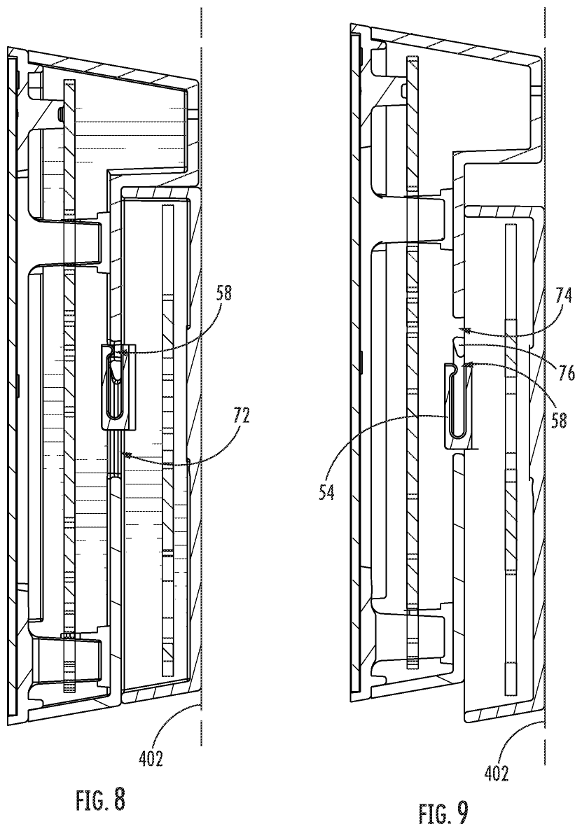

As is discussed further below, there may be various allocations of functions and associated components between the base unit and the second unit. A principal such functionality is display. Accordingly, the second unit includes a display 26 (FIG. 6, e.g., a flat panel LCD or LED display). In the mounted condition, the display displays information (e.g., text including numbers) upright for viewing by a standing user. A second such functionality is manual user input. Associated user input devices may include switches (e.g., pushbutton switches, slide switches, or the like) or may include the display 26 being a touchscreen display (e.g., capacitive or resistive). Accordingly, in such examples, the second unit 24 may be identified as a display and user input unit, a user input/output (I/O) unit, or the like.

Each of the sections 22, 24 comprises a body 32, 34. Exemplary bodies are plastic (e.g., injection molded) such as polystyrene. Each of the sections may further include a circuit board assembly 36, 38. Each of these may in turn include a board (e.g., printed circuit board ((PCB)) 40, 42. The assembly 36 has one or more first electrical connectors 44 (e.g., female multi-conductor socket with upwardly open receptacles) mounted to a front face of the board 40. The assembly 38 has one or more second electrical connectors 46 (FIG. 6) complementary to the first connectors (e.g., a multi-pin male connector in this example with downwardly-projecting pins). In the exemplary embodiment, these are mounted on the rear face of the board 42. This is discussed further below, with the second unit in its mounted condition, the respective connectors are electrically/mechanically mated to each other. The exemplary second unit 24 further comprises a display frame 48 (e.g., molded plastic) for the display 26 and a cover panel 50 (e.g., glass or molded transparent plastic) for the display 26.

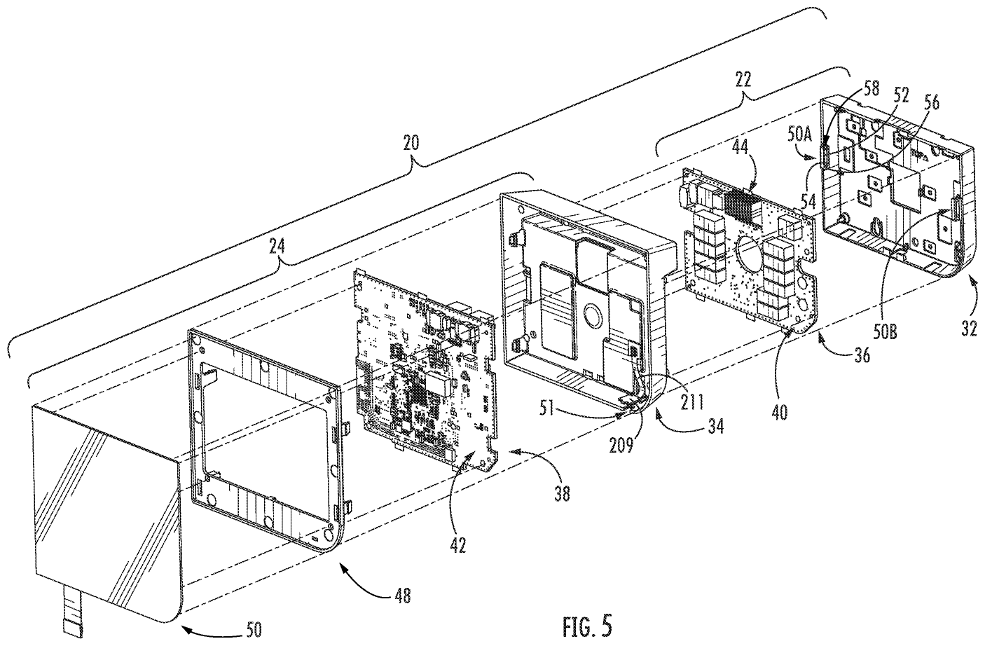

In addition to the electrical connectors, the thermostat has mounting means for mounting the second unit 24 to the base unit 22. Exemplary mounting means provide a detent mounting action securing the mounted/mated condition. Exemplary mounting means includes complementary features on the respective bodies 32, 34. FIG. 5 shows the base unit body 32 as comprising left and right features 50A, 50B. Exemplary features are formed as upwardly open channels having a rear wall 52, a forward wall 54, and a base 56. Near the channel opening, the forward wall includes a rearward projection 58 partially closing the channel opening and ultimately providing the detent mechanism discussed below. Screw mounting slots are on the back of the body 32 just inboard of the features 50A, 50B.

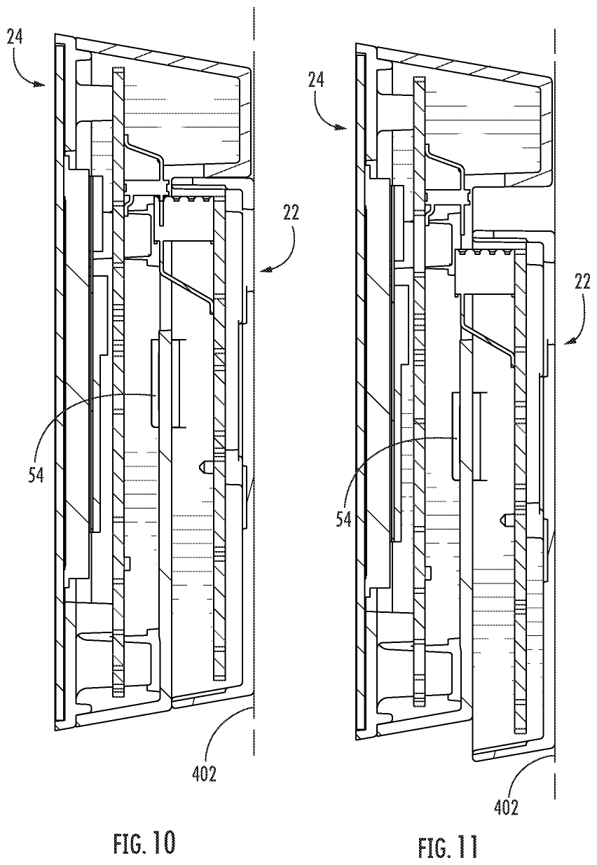

The complementary features 70A, 70B of the second unit body 34 each comprise holes in its rear wall 60 (FIG. 6). The holes comprise pairs of holes including a lower hole 72 and an upper hole 74 with an intact portion 76 of the wall 60 between. In an installation sequence, the base unit is already mounted or fastened to the wall (e.g., via screws or other fasteners) through holes in its rear wall. The second unit is translated toward the base unit upwardly offset. The respective front walls 54 pass through the associated lower holes 72 (FIG. 9) until the second unit bottoms out on the base unit horizontally. Then, the user downwardly translates the second unit. This mates the connectors (FIG. 10) and also causes the projection 58 to pass over the wall portion 76 into the associated upper hole 74 (FIG. 8).

An angled underside of the projection 58 cooperating with wall portion 76 between the holes provides the releasable detenting.

The selection of particular components on the two units 22, 24 may have one or more advantages depending upon the implementation. An example of an allocation of components is discussed below. The allocation(s) may be used to achieve a variety of results.

In one group of examples, a product line comprises a single model of display unit 24 usable with multiple models of base unit 22 facilitating efficiency in stocking and manufacture. The base unit models may differ according to the particular HVAC or other system with which they are used. For example, one base unit model may correspond to the most basic residential heat pump. Another base unit model may correspond to the most basic residential furnace and air conditioner combination. Other base unit models may correspond to more complex HVAC systems adding indoor air quality functionalities. Other base unit models may correspond to systems adding non-HVAC functionalities such as security, lighting, and the like. Variations of these may present different requirements for base unit hardware and programming. Nevertheless, the same model of display unit may be used for all (at least the same hardware, optionally being specifically programmed for use with a particular base unit).

Another potentially overlapping group of examples involve differing levels of functionalities on different models of display unit all usable with one or more models of base unit. Variations may include display quality, the presence of wireless interfaces (WiFi and/or BLE or the like), and so forth.

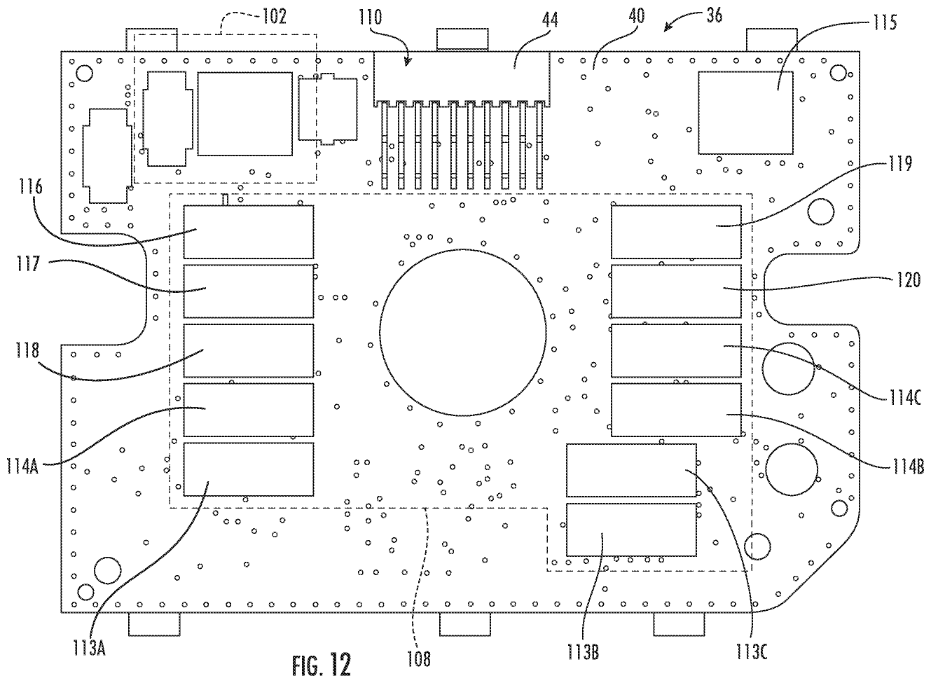

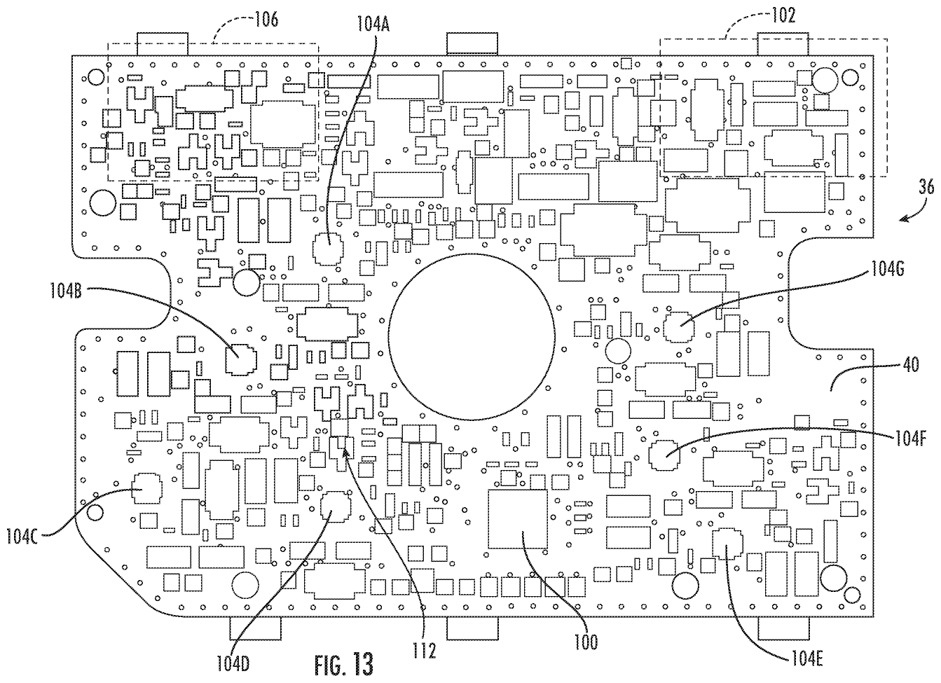

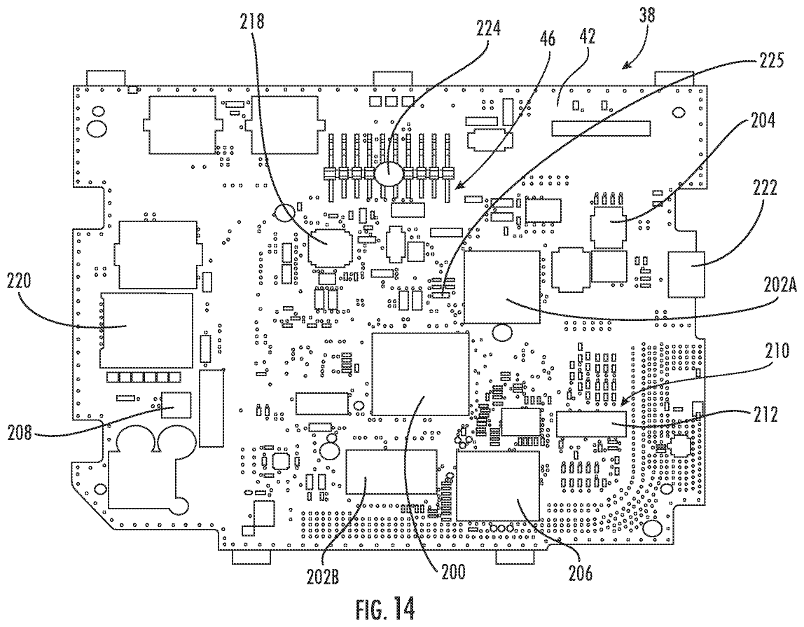

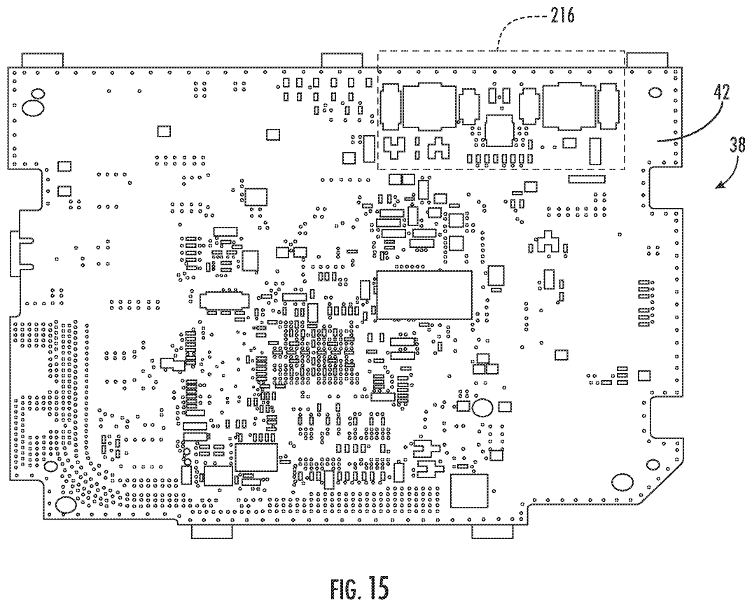

In one exemplary implementation, a basic example of a model of the base unit circuit board assembly 36 includes on the board 40: I/O isolation circuitry (e.g. an isolation device such as a microcontroller 100 (FIG. 13)); power switching circuitry 102; solid state power relays 104A-104G (collectively or individually 114) for equipment control; a 2-wire interface 106; equipment physical interface 108 (FIG. 12) for electrical connection with the HVAC equipment (e.g., tool less connectors); serial interface 110 (e.g., UART or RS-232) for communication with the unit 24 and including the connector 44; and AC power sensing circuits 112 (FIG. 13).

The operation of the basic model of the base unit is defined for discrete low voltage AC control systems where individual AC outputs (113A-113C (collectively or individually 113)—FIG. 13) are defined for various system functional control such as “G” fan 113B, “W1” heat 113A, “Y1” cooling 113C.

In an alternate more advanced model usable with the same second unit 24, the base unit board 40 further includes additional AC outputs 114A-114C (collectively or individually 114)—FIG. 13) for multistage control such as “Y2” second stage cooling 114B, “W2” second stage heating 114A and “O/B” heat pump reversing 114C. The board 40 further bears a wet or dry contact AC/DC power relay 115 connected through interface connectors 119 and 120 for use on many varieties of additional peripheral equipment (e.g., humidifier, dehumidifier, auxiliary make-up air unit, non-HVAC accessories, and the like—not shown).

In addition to the previously defined AC outputs are AC supply inputs RC/V+ power source 117 compatible with outdoor equipment (e.g., air conditioner or heat pump unit) or with 2-wire communications, RH power source 118 compatible with indoor equipment (e.g., furnace , fan coil, and the like), and C/VG common return 116 for RH and RC/V+. The 2-wire interface 106 capability of the RC/V+ power source 117 allows communications over the AC input waveform. This is done by suppressing the negative half of the AC waveform and in its place inserting digital data allowing the thermostat to operate its associated HVAC equipment using only these digital commands. Use of the common low voltage AC power waveform (e.g., 24 VAC) in place of the standard multiplicity of switched

AC outputs may provide the thermostat the ability to operate modern HVAC equipment in structures where only two control wires are present.

For use with either of those base units, the second unit 24 circuit board assembly 38 includes on the board 42: host processor 200 (e.g., microprocessor) which is programmed to execute the systems applications program and communicate with the isolation microcontroller 100; dynamic or volatile memory 202A (e.g., RAM) which is used by the host microprocessor for temporary data storage and non-volatile memory 202B (e.g., FLASH) which holds the applications program and operating system; a real time clock 204 used as a watchdog timer to interrupt and reset the host microprocessor if it should get into a non-recoverable error condition; one or more wireless communication radios 206 (e.g., WiFi and/or Bluetooth (e.g., Bluetooth low energy (BLE) or other protocol); environmental sensors (or connectors therefor) such as an environmental temperature sensor and/or a humidity sensor (connector 208 for a combined temperature and humidity sensor 209 (via flex circuit 211 (FIG. 5) to allow the sensor to be more exposed to the ambient conditions than to board temperature such as by mounting in a compartment 49 molded in the display frame and exposed to a notch/hole 51 in the body 34) e.g., a capacitive temperature and humidity sensor such as the Senserion STS21 of Sensirion AG, Zurich, Switzerland), and the like); sensors to measure board condition such as to monitor internally generated heating (e.g., thermistor or thermocouple 225); the graphic display interface and/or touch interface (shown as a combined interface 210 including the connector 212 for the display 26 and touch layer); the main switching power supply 216 for overall low voltage power; power sequencing hardware 218 to generate and distribute the various direct current voltage levels required by the many electronic components; data interfaces like micro SD card 220 and USB 222 to communicate with development hardware; and serial interface 224 (e.g., UART or RS-232 as noted above) for communication with the base unit interface 110.

The flex circuit 211 and sensor 209 may correspond to those in International Publication WO 2018/038953 A1, “SENSOR MOUNTING ASSEMBLY FOR A CLIMATE CONTROLLER AND METHOD”, Eicher et al., published Mar. 1, 2018, the disclosure of which publication is incorporated by reference herein in its entirety as if set forth at length.

In some examples of the radio(s) 206, Wi-Fi provides communications with a homeowner's network access point to pass data via the internet to cloud storage or the like maintained by the manufacturer of the thermostat or of associated equipment or a service provider and/or BLE provides communication with other system components such as remote temperature and/or humidity sensors for different zones, remote control panels, smart home devices, and the main HVAC equipment itself (furnace, air conditioner, heat pump, fans, dampers, and the like).

An exemplary I/O isolation microcontroller 100 is connected to the solid state relays 104, power switching circuitry 102 and AC power sensing circuits 112 and functions to isolate these peripherals from the host microprocessor 200 such that no powered circuits are applied to the host microprocessor 200 until the host microprocessor is fully powered on. An exemplary I/O isolation microcontroller 100 is a 16-bit device which contains/executes a program which enables the microcontroller to communicate with and control the solid state relays 104 and the power switching circuitry 102. Additionally, the exemplary microcontroller includes an analog to digital converter (not shown) which allows it to measure the AC power sensing circuit 112 voltage levels. Input AC Power (RC/V+ and RH) is required for the solid state relays 104. The power switching circuitry 102 is used to control the sources of this input power. Because input power is not always connected to both the RC/V+ 116 and RH 118, the exemplary power switching circuitry will automatically switch power from the powered circuit to the non-connected circuit without user intervention. Exemplary power switching circuitry 102 includes a mechanical relay under control of the isolation I/O isolation microcontroller 100. When commanded by the host microprocessor 200, the I/O isolation microcontroller 100 also operates the 2-wire interface 106 sending commands to and receiving digital information from the HVAC equipment.

The solid state relays 104 are used to turn on and off AC supply power to the various output connectors 113 and 114. Switched AC power is used on each of the AC equipment control lines from relays 104 to operate its associated function. A relay, rather than a simple switch, is used to perform the switching action. These solid state relays 104 turn their outputs on and off on command of the host microprocessor 200 and return their output status back to the host microprocessor.

The AC power sensing circuits 112 convert the AC voltage to the DC voltage limits acceptable to the microcontroller 100. Exemplary AC power sensing circuits 112 include clamping diodes (not shown) to limit the sensed AC levels to thermostat digital control levels of 3.3 VDC. This signal is further applied to the gate of a field effect transistor (FET) (not shown) switching it on and off. The final output, drawn from the FETs drain, yields a logic high when the positive half of the AC waveform is present and a logic zero when the negative half is missing allowing the microcontroller 100 to sense when a half wave AC input is applied.

The exemplary host microprocessor 200 on assembly 38 is programmed to perform all internal processing and wireless communications while the controller 100 on assembly 36 is strictly responsible for operation of the I/O interfaces as commanded by the assembly 38 host microprocessor 200. Exemplary such internal processing includes: reading from the combined temperature and humidity sensor 209 to determine the ambient temperature and humidity; operating the display and capacitive touch interface 26 to allow for external input of control parameters for ambient environmental control; measuring the value of the onboard temperature sensor 225 to monitor thermostat internal temperature; and communicating with associated equipment and/or cloud services using the wireless communications interface 206.

An example of a system where the wiring 410 is eleven wires has those wires and associated contacts as:

C/VG—common AC return for R_{C} and R_{H} (C);
R_{C}/V+—full wave 24 VAC power from outdoor equipment (e.g., air conditioner or heat pump);
R_{H}—24 VAC power from indoor equipment (e.g., furnace or fan coil);
W1—first stage heat;
W2—second stage heat;
G—fan (e.g., furnace or fan coil);
Y1—first stage cooling;
Y2—second stage cooling;
O/B—heat pump reversing valve (not used if only an AC unit);
D1/HUM—(a) when software configured as HUM will control humidifier (if present) or (b) when software configured (D1) as a dry contact relay this serves as the first half of a mechanical relay;
D2—(a) inactive when software configured as HUM or (b) active when configured as a dry contact relay to serve as the second half of the mechanical relay.

In a 2-wire control variation on the eleven wire system, otherwise similar, the remaining outputs are disabled and the active outputs are:

C/VG—common AC return for 2-wire (VG);
R_{C}/V+—half wave 24 VAC from remote module 2-wire interface.

The thermostat may be made using otherwise conventional or yet-developed materials and techniques.

The apportionment of components and functions between the two units may serve various purposes. One area of examples involves balancing component cost and component reliability. It may be desired to assign components that have high cost and/or high reliability (or a high balance of the two) to one unit while assigning components with low cost and/or low reliability (or low balance of the two) to the other. This makes repairs less expensive if the unit with low cost components (thus likely the lower cost unit) can be replaced while reusing the other unit. Key examples of high cost and low failure rate components are the touchscreen 26, the memory 202A, 20B, and the host processor 200. Key examples of low cost and high failure rate components are the solid state relays 104.

The use of “first”, “second”, and the like in the description and following claims is for differentiation within the claim only and does not necessarily indicate relative or absolute importance or temporal order. Similarly, the identification in a claim of one element as “first” (or the like) does not preclude such “first” element from identifying an element that is referred to as “second” (or the like) in another claim or in the description.

Use may be in wall-mounted controls other than thermostats and beyond HVAC. Examples include security systems, fire alarm and/or suppression systems, and the like.

One or more embodiments have been described. Nevertheless, it will be understood that various modifications may be made. For example, when applied to an existing basic HVAC system or baseline thermostat, details of such configuration or its associated use may influence details of particular implementations. Accordingly, other embodiments are within the scope of the following claims.

1. A wall mountable user interface unit (20) being a thermostat and comprising:
a first section (22) comprising:
a body (32) mountable to a wall and having first features (50A, 50B);
power relays (104); and
a first interface (110) for two-way communication with the second section and including a first electrical connector (44); and
a second section (24) mountable to and demountable from the first section and comprising:
a body (34) having second features (70A, 70B) for holding the second section to the first section in a mounted condition;
a second interface (224) for two-way communication with the first section and including a second electrical connector (46) carried by the second section body and mated to the first electrical connector in the mounted condition;
a processor (200); and
a display (26),
the thermostat having:
a first temperature sensor being an environmental temperature sensor (209); and
a second temperature sensor being an internal PC board temperature sensor (225).

2. The wall mountable user interface unit of claim 1 wherein:
the first and second interfaces are serial interfaces.

3. The wall mountable user interface unit of claim 1 wherein:
the second section is installable to the first section to mate the second electrical connector to the first electrical connector by a downward translation.

4. The wall mountable user interface unit of claim 1 wherein:
the first section body and the second section body comprise a detent mechanism (58, 74, 76) securing the mounted condition.

5. The wall mountable user interface unit of claim 4 wherein the detent mechanism comprises:
a pair of upwardly open channels on one of the first section body and the second section body;
a detenting projection (58) on a wall of at least one of the upwardly open channels;
a pair of holes on the other of the first section body and the second section body complementary to the pair of channels; and
at least one detenting hole (74) complementary to the detenting projection.

6. The wall mountable user interface unit of claim 1 wherein the first temperature sensor and the second temperature sensor are in the second section.

7. The thermostat of claim 6 wherein the first section and second section are in detented engagement.

8. The thermostat of claim 6 wherein the first section further comprises:
an input/output isolation microcontroller (100);
power switching circuitry (102); and
AC power sensing circuits (112).

9. The thermostat of claim 8 wherein the second section further comprises:
volatile memory (202A) and non-volatile memory (202B); and
a radio(206) for wirelessly communicating with associated HVAC equipment and sensors.

10. The wall mountable user interface unit of claim 1 wherein the first section further comprises:
a 2-wire interface (106)for equipment control when only two wires for supply power are present in the installation.

11. The wall mountable user interface unit of claim 10 wherein the 2-wire interface is configured to communicate and control associated HVAC equipment using voltage 24 VAC power waveform.

12. The wall mountable user interface unit of claim 1 wherein the first section is directly fastened to a wall.

13. A method for using a wall mountable user interface unit (20), the wall mountable user interface unit comprising:
a first section (22) comprising:
a body (32); and
a first electrical connector (44); and
a second section (24) comprising:
a body (34);
a second electrical connector (46) carried by the second section body;
a display (26); and
a processor (200),
the method comprising:
with the first section body mounted to a wall (400), installing the second section to the first section to mate the second electrical connector to the first electrical connector by a downward translation.

14. The method of claim 13 wherein:
the installing comprises a translation toward the wall prior to the downward translation.

15. The method of claim 14 wherein:
the installing comprises passing features of the first section body through apertures in the second section body.

16. The method of claim 13 wherein:
the installing is a detented installing.

17. A wall-mounted user interface unit (20) comprising:
a first section (22) mountable to a wall and comprising:
a body (32) having first features (50A, 50B); and
a first electrical connector (44); and
a second section (24) mountable to and demountable from the first section and comprising:
a body (34) having second features (70A, 70B) for holding the second section to the first section in a mounted condition;
a second electrical connector (46) carried by the second section body and mated to the first electrical connector in the mounted condition; and
a display (26),
wherein, with the first section body mounted to a wall (400), the second section is installable to the first section to mate the second electrical connector to the first electrical connector by a downward translation.

18. The wall-mounted user interface unit (20) of claim 17 wherein the second section comprises:
a first temperature sensor being an environmental temperature sensor (209); and
a second temperature sensor being an internal PC board temperature sensor (225).

19. The method of claim 16 wherein:
the detented installing is via upwardly-open channels (50A, 50B) on the first section passing through holes in a rear wall of the second section and then receiving the rear wall via the downward translation.
